(19) United States
(12) Patent Application Publication
(10) Pub. No.: US 2025/0130284 A1
(43) Pub. Date: Apr. 24, 2025

(54) MEASUREMENT SYSTEM AND MEASUREMENT METHOD FOR MEASURING ENERGY CELLS

(71) Applicant: KÖRBER TECHNOLOGIES GMBH, HAMBURG (DE)

(72) Inventors: Johannes MÜLLER, HAMBURG (DE); Christian Frédéric ADOLFF, HAMBURG (DE)

(21) Appl. No.: 18/833,777

(22) PCT Filed: Feb. 13, 2023
(86) PCT No.: PCT/EP2023/053484

§ 371 Date: Jul. 26, 2024

(30) Foreign Application Priority Data
Feb. 24, 2022 (DE) 10 2022 104 472.6

(51) Int. Cl. G01R 31/389; H01M 10/42

(52) U.S. Cl. CPC G01R 31/389; H01M 10/4285

(57) ABSTRACT

The invention relates to a measurement system for measuring energy cells, for example battery cells, in particular dry monocells, wherein the measurement system has an alternating voltage measuring bridge or a self-balancing measuring bridge (auto-balancing bridge) and is designed to measure the electrical capacitance (C) and/or the ohmic resistance (R) of an energy cell by means of a high-frequency measurement. The invention further relates to a corresponding method.

The present invention relates to a measurement system for measuring energy cells in accordance with the preamble of claim 1 and to a measurement method in accordance with the preamble of claim 5.

During the manufacture of energy cells or energy storage cells, in particular battery cells, foreign bodies can become deposited between the individual layers (anode, separator and cathode) from which the energy cell is constructed. This can, for example, destroy the separator layer when pressed together, which can lead to a short circuit in the individual cell and thus render it unusable.

Energy cells, in particular battery cells, are usually formed by a stack of monocells. Detecting such a short circuit before stacking the monocells is therefore of great importance, since a single defective monocell renders the entire stack or battery cell unusable. A short circuit can occur, for example, if the resistance deviates significantly from the typical insulation resistance of the monocell, for example if the resistance is smaller than a specified limit resistance.

In order to further reduce the production costs of battery manufacturing, the production speed must, among other things, be further increased.

The invention is based on the object of providing a measurement system and a measurement method which allow greater process reliability and process speed in the manufacture of energy cells.

The invention achieves this object by the features of the independent claims. Further preferred embodiments of the invention can be found in the dependent claims and the associated descriptions and the drawings.

Accordingly, in order to achieve the object, a measurement system for measuring energy cells, preferably battery cells, in particular dry monocells, is proposed. The measurement system comprises an alternating voltage measuring bridge or a self-balancing measuring bridge (auto-balancing bridge) and is designed to measure the electrical capacitance C and/or the ohmic resistance R of an energy cell by means of a high-frequency measurement.

In principle, the term “high frequency” means, in contrast to the microwave range, fields with a frequency below 100 MHz. The frequency is usually 0.5 kHz, for example, or 1 kHz, or 100 kHz, for example. Furthermore, a high-frequency measurement is distinguished from a direct current measurement of an energy cell, in particular a battery cell, wherein a direct current measurement determines the resistance via charging and/or discharging of the cell.

An alternating voltage measuring bridge or self-balancing measuring bridge (auto-balancing bridge) allows rapid measurement of the energy cell, in particular a dry monocell of a battery cell. The measurement can be carried out at low currents and voltages, which, among other things, allows simple EMC-compliant implementation. This means that there is also a low power requirement and the risk of contact for an operator is significantly reduced. Furthermore, this allows a compact design to be achieved, which further simplifies integration into a production process.

In addition to measuring the ohmic resistance, the proposed measurement system allows the measurement of the capacitance of a monocell, so that in addition to checking for a short circuit, further information about the quality of the respective energy cell, in particular the respective monocell, is available.

An alternating voltage measuring bridge or self-balancing measuring bridge (auto-balancing bridge) is a measuring circuit in which the current through a reference impedance is varied in comparison to the current through an element or energy cell to be measured until the sum of the two currents is 0. The adjustment is usually carried out by a targeted amplitude and phase change of the current flowing through the reference impedance. The complex impedance of the element or energy cell to be measured can then be calculated from the set amplitude and phase of the current through the reference impedance. If, for example, there is a parasitic short circuit (parallel low resistance), the angle to be set or the phase position and the amplitude of the control current change significantly. The detection of a short circuit, i.e. a low ohmic resistance, can thus be carried out by comparing the angle of the control current to be set with a limit value.

The energy cell to be measured can in particular be a monocell of a Li battery. The measurement system is particularly suitable for measuring dry monocells of a battery, i.e. a monocell that is not yet filled with electrolyte liquid. The monocell is primarily capacitive, which is why the reference impedance should also be capacitive. The measuring electronics, in particular the alternating voltage measuring bridge or self-balancing measuring bridge (auto-balancing bridge), is preferably adapted to the capacitance of the energy cell, in particular the monocell, which can be comparatively large.

In accordance with a further development, it is proposed that the measurement system is designed to measure energy cells of a continuous product stream of energy cells. In this way, online quality control can be carried out without reducing production speed.

It is further proposed that the measurement system has a drum, wherein the measurement system is designed to measure energy cells conveyed on the drum. This allows the energy cell, in particular the monocell, to be measured during conveyance on the drum, so that an online process control can be carried out for each energy cell, in particular each monocell, in a manufacturing process without negatively affecting the process speed.

Alternatively, it is proposed that the measurement system has a conveyor belt, wherein the measurement system is designed to measure energy cells conveyed on the conveyor belt. This results in comparable advantages in terms of ensuring process quality while maintaining high process speed.

Furthermore, in order to achieve the object, a measurement method for measuring energy cells, preferably battery cells, in particular monocells, is proposed, wherein the energy cell is measured by means of a self-balancing bridge measuring method (auto-balancing bridge method) with respect to electrical capacitance C and/or ohmic resistance R.

The energy cell can be measured very quickly by means of the measurement method, so that every energy cell, in particular every monocell, can be measured in a manufacturing process without negatively affecting the process speed. Determining the capacitance provides information about the quality of the monocell and its production. The measurement of the energy cells is preferably carried out during the continuous conveyance of the energy cells.

In accordance with a further development, it is proposed that the measurement of the energy cell be carried out on a running conveyor belt or a rotating drum. This allows a continuous product stream, which has a positive effect on the process speed and energy efficiency of the manufacturing process.

The energy cell to be measured, in particular the monocell, is preferably a so-called dry energy cell, so that no liquid electrolyte has been added to the energy cell up to the time of measuring the energy cell.

It is further proposed that after measuring the ohmic resistance of an energy cell, the ohmic resistance R is compared with a limit value, and the energy cell is ejected from a product stream if this limit value is not reached.

In this way, the quality of energy cell production can be achieved at a high level, whereby the use of monocells in a stack to form a stacked energy cell can be avoided, in particular when measuring the monocells in the product stream. This avoids further waste that would occur when using a defective monocell in a stacked arrangement.

In accordance with a further development, it is proposed that after measuring the electrical capacitance C and/or the ohmic resistance R of an energy cell, in particular a monocell, the respective electrical capacitance C and/or the ohmic resistance R is stored in a data processing device.

This allows for continuous quality monitoring of energy cell production.

In accordance with a further development, it is proposed that after measuring the electrical capacitance C of an energy cell, the electrical capacitance C is compared with an upper and/or lower limit value, and the energy cell is ejected from a product stream if the respective limit values are exceeded or not reached. Such deviations outside of definable limit values may indicate inferior quality, for example due to lamination errors, which may be caused by temperature deviations, among other things.

In accordance with a further development, it is proposed that after measuring the electrical capacitance C of a plurality of energy cells, in particular monocells, which may each have different electrical capacities C, are combined to form a stack with a total capacitance C_ges above a lower limit value and below an upper limit value.

In this way, energy cells, which are formed from a stacked arrangement of monocells, can be manufactured with a constant property profile.

The invention is explained below using preferred embodiments with reference to the accompanying drawings. In the drawings:

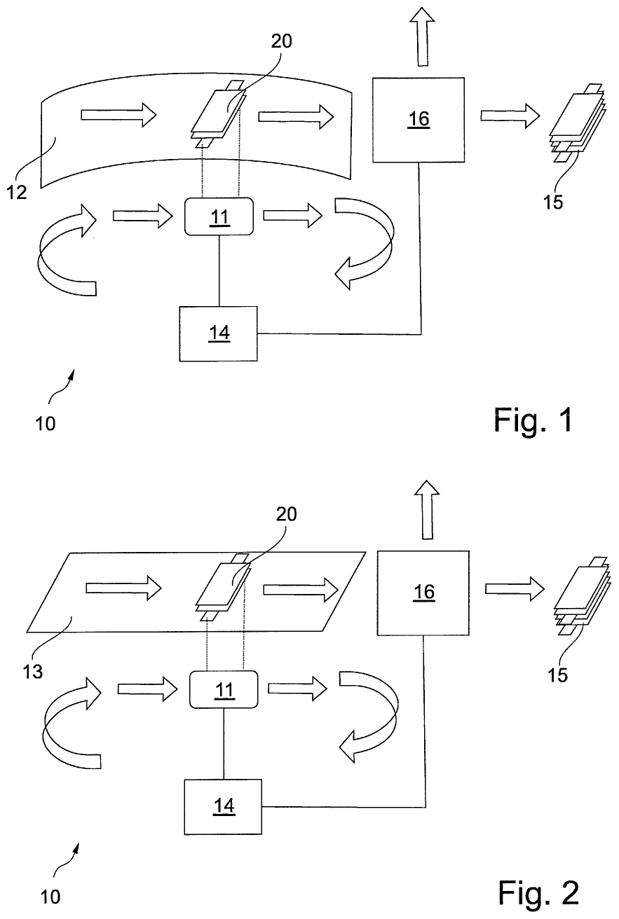

FIG. 1 shows a measurement system for measuring monocells on a drum; and

FIG. 2 shows a measurement system for measuring monocells on a conveyor belt.

FIG. 1 schematically shows an embodiment of a measurement system 10 for measuring energy cells 20. The measurement system 10 has a self-balancing measuring bridge (auto-balancing bridge) 11, with which an energy cell 20, in this embodiment a dry monocell for a Li battery, is contacted.

The self-balancing measuring bridge (auto-balancing bridge) 11 measures the energy cell 20 by means of a high-frequency measurement with respect to electrical capacitance C and ohmic resistance. The self-balancing measuring bridge (auto-balancing bridge) 11 allows both values to be measured in a simple manner in one short measurement.

In the embodiment of FIG. 1, the energy cell 20 is conveyed on a drum 12 in a continuous product stream. As illustrated by the arrows in FIG. 1, the measurement of the energy cell 20 is carried out by the measurement system 10 during continuous conveying. This, together with the short measurement time by means of the self-balancing measuring bridge (auto-balancing bridge) 11, allows online measurement of the energy cell 20 without interrupting or slowing down the product stream.

FIG. 2 schematically shows a further embodiment of a measurement system 10, wherein the energy cell 20, in contrast to the embodiment of FIG. 1, is continuously conveyed on a conveyor belt 13, while the energy cell 20 is measured by means of the self-balancing measuring bridge (auto-balancing bridge) 11.

In the embodiment of FIGS. 1 and 2, a data processing device 14 is provided which is designed to store the recorded measurement data, preferably ohmic resistance R and electrical capacitance C.

Both measurement data of the respective energy cell 20 can be used to evaluate the quality. The stored measurement data of the respective energy cell 20 can then be compared in the data processing device 14 with specified limit values, wherein in particular energy cells 20 with an ohmic resistance below a certain limit value are usually unusable due to a detected short circuit in the energy cell 20. In this way, unusable energy cells 20 can be detected in the running product stream and removed from the product stream by an ejector 16 controlled by the data processing device. Any short circuits in a monocell can therefore be detected at an early stage, so that these unusable energy cells 20, in particular monocells, are not stacked into a stack 15, for example. The measurement can therefore prevent the manufacture of unusable stacks 15 due to short circuits in individual monocells.

In an advantageous embodiment, the total capacitance C_ges of a stack 15 with a fixed number of individual energy cells 20 or monocells can be optimised by means of the data processing device 14, so that measured energy cells 20 with their respective electrical capacities C can be sorted and combined to form a plurality of stacks 15 that lie in a specified range of a total capacitance C_ges or an average capacitance of the individual energy cells 20 of the stack 15, whereby the same properties can be achieved across a large number of stacks.

1. A measurement system for measuring energy cells
wherein the measurement system has an alternating voltage measuring bridge or a self-balancing measuring bridge (auto-balancing bridge) and is designed to measure the electrical capacitance C and/or the ohmic resistance R of an energy cell by means of a high-frequency measurement.

2. The measurement system according to claim 1, wherein the measurement system is designed to measure energy cells of a continuous product stream of energy cells.

3. The measurement system according to claim 1, wherein the measurement system has a drum, wherein the measurement system is designed to measures energy cells conveyed on the drum.

4. The measurement system according to claim 1, wherein the measurement system has a conveyor belt, wherein the measurement system is measures energy cells conveyed on the conveyor belt.

5. A measurement method for measuring energy cells, wherein the energy cell is measured by means of a self-balancing bridge measuring method (auto-balancing bridge method) with respect to electrical capacitance C and/or ohmic resistance R.

6. The measurement method according to claim 5, wherein the measurement of the energy cell is carried out on a running conveyor belt or a rotating drum.

7. The measurement method according to claim 5, wherein after measuring the ohmic resistance of an energy cell, the ohmic resistance R is compared with a limit value and the energy cell is ejected from a product stream if this limit value is not reached.

8. The measurement method according to claim 5, wherein after measuring the ohmic resistance R of an energy cell, the ohmic resistance R is compared with a limit value and the energy cell, is stacked with further energy cells if this limit value is exceeded.

9. The measurement method according to claim 5, wherein after measuring the electrical capacitance C and/or the ohmic resistance R of an energy cell, the respective electrical capacitance C and/or the ohmic resistance R is stored in a data processing device.

10. The measurement method according to claim 5, wherein after measuring the electrical capacitance C of an energy cell, the electrical capacitance C is compared with an upper and/or lower limit value, and the energy cell is ejected from a product stream if the respective limit values are exceeded or not reached.

11. The measurement method according to claim 5, wherein after measuring the electrical capacitance C of a plurality of energy cells which can each have different electrical capacities C, are combined to form a stack with a total capacitance C_ges above a lower limit value and below an upper limit value.

12. The measurement system according to claim 1, wherein the energy cells are battery cells.

13. The measurement system according to claim 1, wherein the energy cells are monocells.

14. The measurement method according to claim 5, wherein the energy cells are battery cells.

15. The measurement method according to claim 5, wherein the energy cells are monocells.
